(19) United States
(12) Patent Application Publication
(10) Pub. No.: US 2010/0108889 A1
(43) Pub. Date: May 6, 2010

(54) METHOD AND APPARATUS FOR IMAGING AN LCD USING TERAHERTZ TIME DOMAIN SPECTROSCOPY

(76) Inventors: Yaochun Shen, Cambridge (GB); Alessia Portieri, Cambridge (GB); Donald Dominic Arnone, Cambridge (GB)

Correspondence Address: DICKSTEIN SHAPIRO LLP, 1825 EYE STREET NW, Washington, DC, 20006-5403, US

(21) Appl. No.: 12/524,996

(22) PCT Filed: Jan. 29, 2008
(86) PCT No.: PCT/GB08/00302

§ 371 Date: Jan. 13, 2010

(30) Foreign Application Priority Data
Jul. 29, 2007 (GB) 0701652.0

(51) Int. Cl. G01J 5/02; G01R 27/04

(52) U.S. Cl. 250/341.1; 324/640; 324/643; 250/343

(57) ABSTRACT

A method configured to investigate an LCD structure, the method comprising: irradiating an LCD structure with pulsed radiation having at least one frequency in the range from 40G Hz to 100 THz; detecting radiation which has been transmitted through or reflected by the structure; determining information about the structure by measuring a quantity at least related to the amplitude of the detected radiation.

The present invention relates to the field of investigation and imaging using THz radiation. More specifically, the present invention relates to the field of investigating and imaging LCD using pulsed THz radiation.

Liquid crystal displays (LCDs) are an increasingly important component of electronic devices, from consumer goods (flat panel displays in TVs, mobile phones) through to specialized scientific uses in a variety of applications ranging from medical imaging of cancer through to defense.

The key component of any LCD is the liquid crystal layer that is used to control the amount and colour of light emitted from the display at different pixels. The fabrication of an LCD and especially the introduction of the liquid crystal layer involves a detailed and highly-controlled process during which contamination due to water or other impurities (either present during, or used in, the fabrication process) can result in failure of the device. Even a small amount of water in 1-2 pixels in a display can eventually lead to failure or rejection of the entire display.

It is desirable to check for contaminants before the LCD elements are mounted onto a display back plane containing the further electronic and optical components. Currently, many techniques including visible ‘light on’ tests have been performed at this point to try to detect water or other impurities. These tests however suffer from lack of sensitivity and/or interference from other elements in the display.

It is also difficult to find a technique that both isolates and probes the region around the liquid crystal layer in the sandwich and searches for contaminants. Infrared technology, has been investigated as a possible technique, but suffers from a number of deficiencies. First of all, it does not have the 3D imaging or depth discrimination to isolate the region around the liquid crystal. Secondly, the presence of glass slides and, in particular, the metal electrodes, considerably degrades the spectral imaging capabilities of this technology. As a result, infrared has not been effective at determining water or other contamination an LCD element. Other techniques such as light scattering and microwave heating have been attempted, but suffer from low sensitivity or other limitations.

The present invention addresses the above problems and in a first aspect provides a method configured to investigate an LCD structure, the method comprising:
irradiating an LCD structure with pulsed radiation having at least one frequency in the range from 40 GHz to 100 THz;
detecting radiation which has been transmitted through or reflected by the structure;
determining information about the structure by measuring a quantity at least related to the amplitude of the detected radiation.

The applicants have found that terahertz pulsed radiation provides a particularly useful tool for investigating LCD structures and for determining 3-dimensional information about the structure inside the LCD. The technique can also be used to chemically or structurally detect and possibly identify defects or features inside of the LCD.

More preferably radiation in the frequncy range from 50 GHz to 10 THz is used, even more preferably in the frequency range from 100 GHz to 5 THz.

The method may be configured to investigate a layer or a plurality of layers inside the structure. To achieve this, the method further comprises identifying at least one pulse from the detected radiation which has been influenced by said layer or layers of interest. More preferably the pulse has been strongly influenced by said layer or layers of interest, e.g. the pulse arises from a reflection from an interface adjacent or near said layers of interest. The pulse might also arise from a transmission through said layer.

The liquid crystal layer itself may be studied using this technique. The method can be used to determine whether or not a liquid crystal layer is present in the region of the sample where it should be located. This may be achieved by studying the detected radiation to look for the presence or absence of features associated with a liquid crystal layer. Alternatively detected radiation may be compared with a reference. The reference may be a completely different sample or it may be regions from a part of the test sample which are known to be good.

The present invention may also be used to determine if there is a contaminant in the liquid crystal layer. For example, it may be used to determine water contamination. Water is a strong absorber of terahertz radiation. Therefore, samples from a region which is contaminated with water will be sharply attenuated. Alternatively or additionally, the presence of water contamination or other contaminants may be determined by deriving spectral information from the detected THz radiation and comparing the spectral information with a known spectra for the contaminant. The presence or absence of a liquid crystal layer may also be determined by deriving a spectra from the region where the liquid crystal layer should be located and comparing it with a reference spectra. Similarly, the THz refractive index, or THz pulse characteristics influenced by the refractive index, can be used to detect the presence of the liquid crystal and impurities from information in the time or frequency domains of the THz pulse.

The structure may preferably be examined in reflection mode. In reflection mode, sharp peaks will be seen due to reflections arriving from different interfaces. In an LCD structure, there are many sharp interfaces. The structure generally comprises a sandwich structure where a liquid crystal layer is sandwiched between two polyamide layers. The two polyamide layers in turn are sandwiched between electrodes and the two electrodes are themselves sandwiched between two glass slides. Reflections from the glass slide/electrode/polyamide layer interface will be sharp and can be easily distinguished in a reflection terahertz measurement. This allows the signal due to the liquid crystal region to be clearly identified.

It is also possible to identify information from a certain part of the structure using a transmission measurement as the height of the peak at different delay times will change due to the presence of different constituents of the sample. Also, transmission measurements are affected by secondary reflections and the secondary reflections may be analysed in the same manner as other direct reflection measurements.

A particularly advantageous way of looking at this information is to determine the interface index. The interface index is related to the amplitude and is calculated by measuring the height of the main peak due to a reflection from an interface where the reflection is strongly influenced by the layer of interest divided by the height of the peak due a reflection from an interface which is not affected by the layer. Typically, the reflection which is not affected by the layer will be the entry interface of the sample. This provides a way of normalising the signal from the layer of interest.

The interface index for the glass/polyamide interface has been found to differ considerably dependent on the presence of the LCD layer and any contamination within that layer. The detected radiation may be analysed in the time domain. Initially, it is preferable if analysis is performed in the time domain as this allows the location of reflections to be easily determined since the delay time is equivalent to the penetration depth of the radiation into the sample.

It is possible to use the magnitude and sign (increase or decrease) in the interface index, or some quantity related to the reflection amplitude, to determine the presence and origin of the defect or contaminant. It is possible to determine such changes from knowledge of the different optical properties (refractive indices and absorption coefficients in the THz) of the different constituents and contaminants, but a more straightforward way is to measure the change in a structure due to the presence of a known (e.g. deliberately included) contaminant, and search for such differences in the interface index or other quantities in actual usage of the method.

Interface index is an example of a quantity related to the amplitude of the detected radiation. Other examples include, but are not limited to, the refractive index, absorption index and corrections or normalisation of the original amplitude data. The amplitude itself may also be studied.

To perform an analysis of the actual components, it is desirable if the radiation is analysed in the frequency domain as this can be compared with known spectra.

To analyse a whole sample, it is preferable if measurements are performed at a plurality of different points across the structure. This allows an image of the structure to be made up. The image may be derived by looking at the signal from a certain layer within the structure across the whole of the structure. This allows an image of the structure to be constructed showing water contamination at various parts of the structure. Alternatively, an image of the structure may also be determined to show defects. Terahertz radiation allows layers and defects of less than ˜50 microns to be imaged.

The present invention may advantageously be used to examine layers which are located under highly scattering or opaque media. For example, layers which are located between thin metal electrodes. Also, the present invention may be used to determine information about layers less ˜50 microns wide.

In a second aspect, the present invention provides an apparatus for investigating an LCD structure, comprising:
a mount configured to hold an LCD for investigation;
a source of THz radiation configured to irradiating an LCD located in said mount with pulsed radiation having at least one frequency in the range from 40 GHz to 100 THz;
a detector for detecting radiation which has been transmitted through or reflected by the LCD; and
a computer for determining information about the LCD by measuring a quantity at least related to the amplitude of the detected radiation.

The mount may be movable to allow the whole of an LCD to be imaged. Alternatively, the mount may be configured so that multiple LCDs can be examined in a production line movement.

Finally, the mount may take the form of a robot arm which allows LCDs to be selected moved to be imaged and moved back to a storing point and a subsequent LCD to be selected moved to be imaged etc.

The present invention will now be described with reference to the following non-limiting embodiments in which:

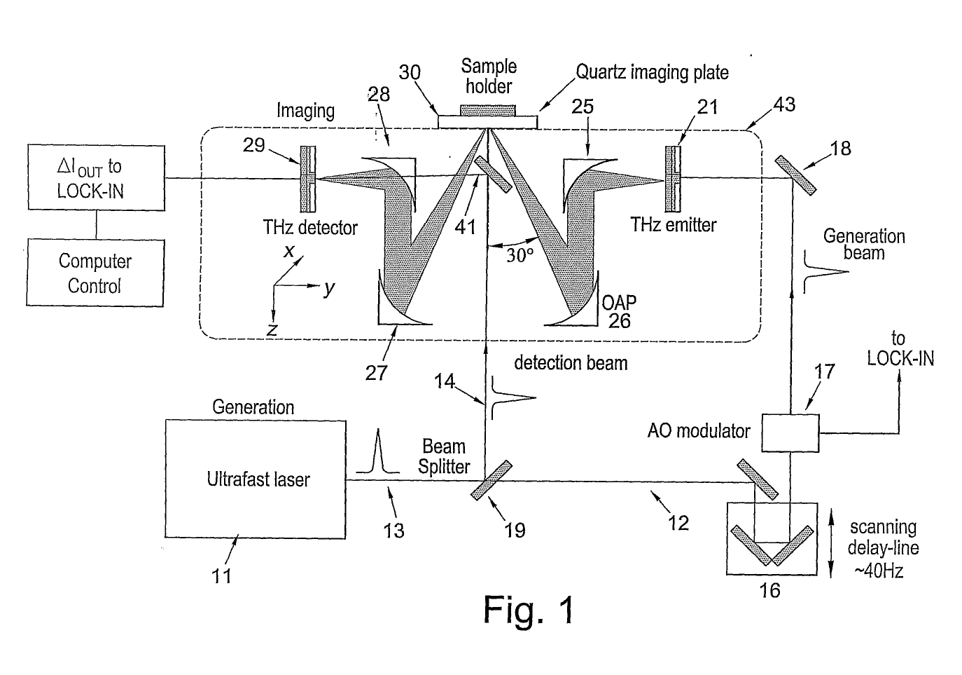

FIG. 1 is a schematic of a terahertz imaging system configured for reflection measurements;

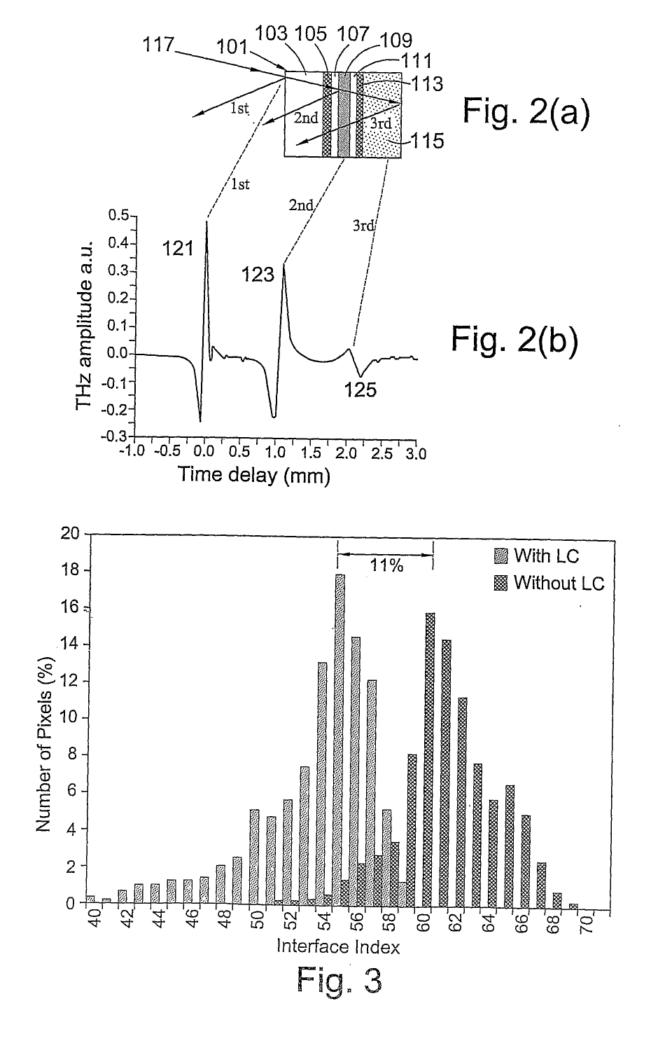

FIG. 2a is a schematic of the basic structure of an LCD element and FIG. 2b is a plot of the amplitude of the reflected terahertz waveform over time showing the signals from the different regions of the LCD element of FIG. 2a;

FIG. 3 is a plot of the plot of the distribution of the interface index for a sample with a liquid crystal layer and a sample without a liquid crystal layer;

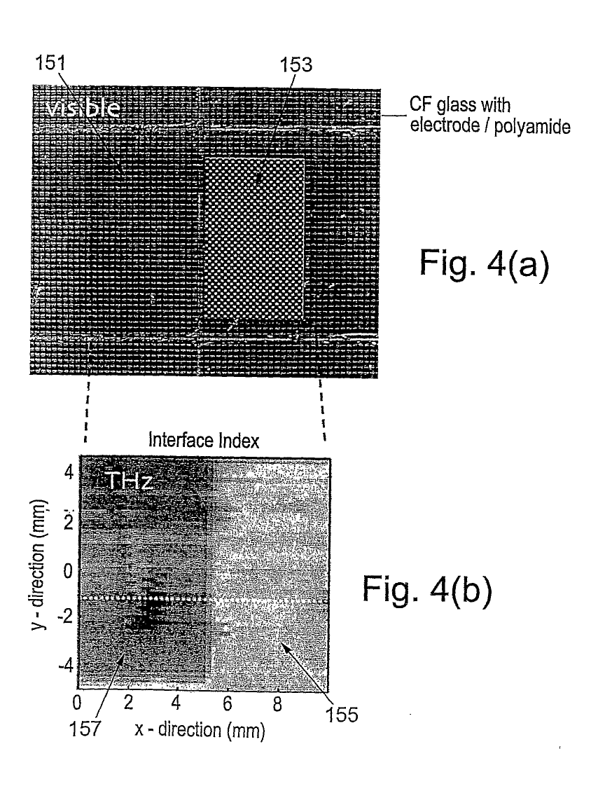

FIG. 4a is a visible image structure comprising glass with an electrode/polyamide with water contamination and FIG. 4b shows the corresponding terahertz image of this structure indicating the presence of water;

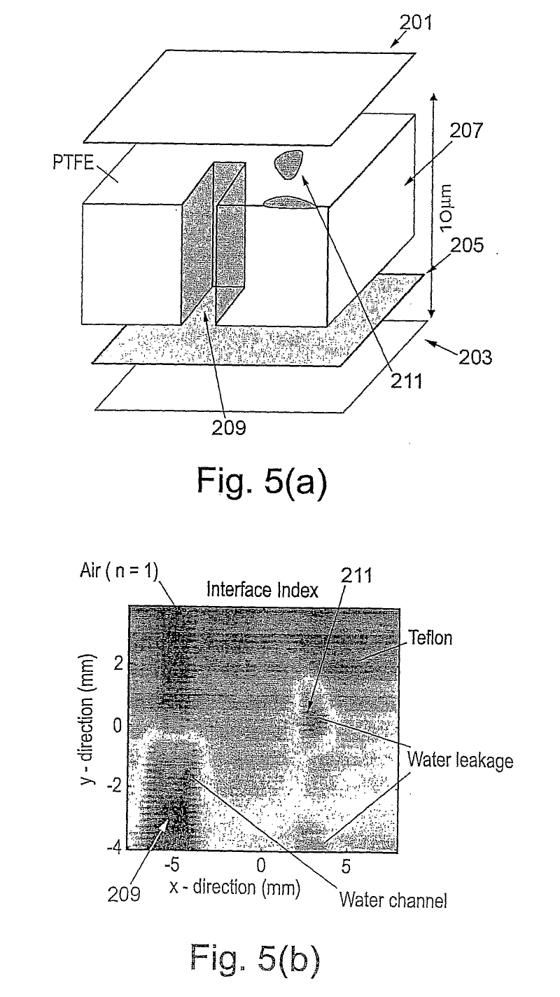

FIG. 5a is a 3-dimensional schematic of a liquid crystal structure and FIG. 5b is a terahertz image of the structure of FIG. 5a taken from the region encompassing the liquid crystal interface;

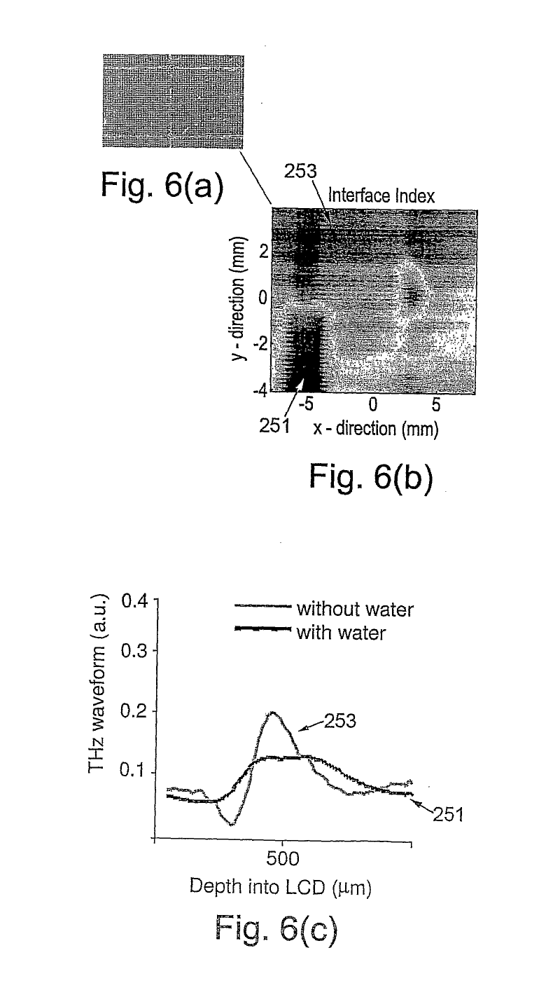

FIG. 6a is a visible image of an LCD structure with water contamination, FIG. 6b is the same region image using terahertz radiation and FIG. 6c is a time domain terahertz measurement showing the different terahertz signals from the regions of FIG. 6b;

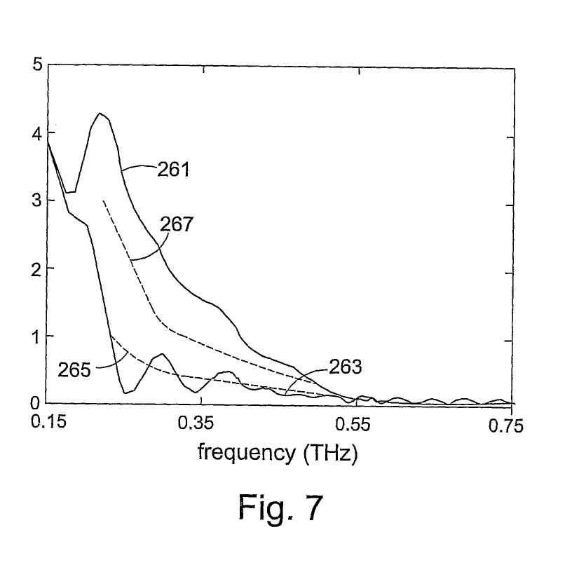

FIG. 7a shows the plot of FIG. 6c converted into the frequency domain;

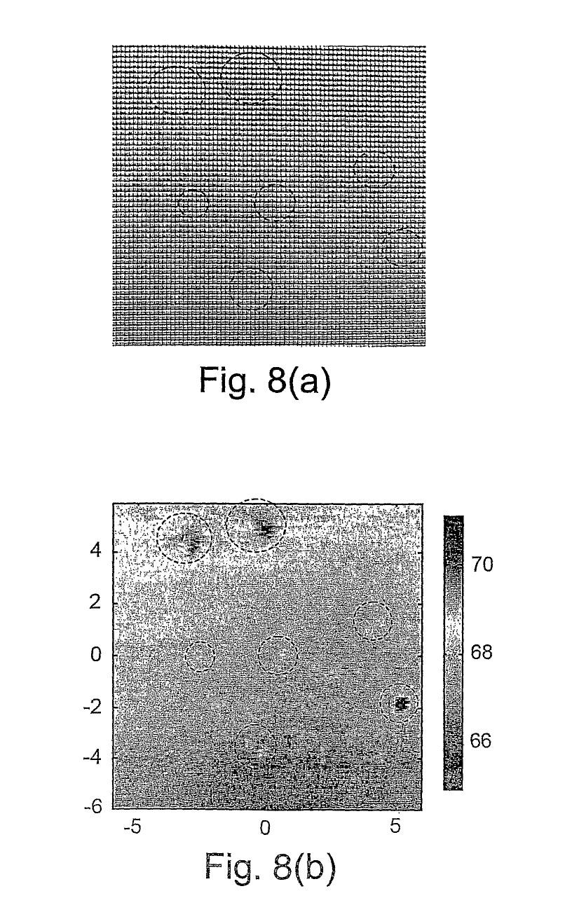

FIG. 8a is visible image of an LCD structure and FIG. 8b is the corresponding terahertz image of FIG. 8a showing defects;

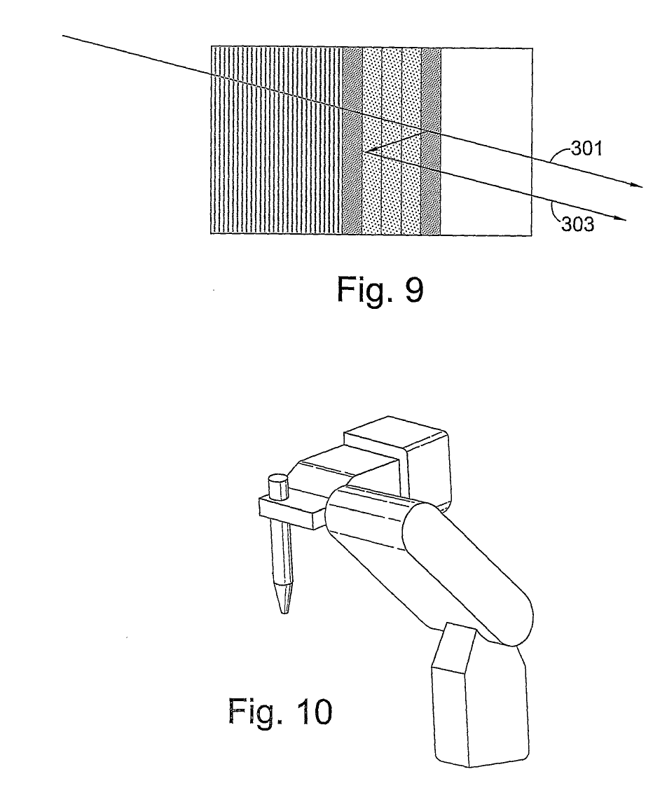

FIG. 9 is a schematic of an LCD structure used to explain transmission measurements; and

FIG. 10 is a schematic of a robot arm.

FIG. 1 is a schematic of a terahertz reflection system which may be used to obtain terahertz data. The system shown is a so-called terahertz ‘flat-bed’ scanner system. The apparatus comprises an ultra-short pulsed laser 11 which may be, for example, Ti:sapphire, Yb:Er doped fibre, Cr:LiSAF, Yb:silica, Nd:YLF, Nd:Glass, Nd:YAG or Alexandrite laser. This laser 11 emits pulses of radiation 13, such as a collimated beam of pulses, each of which comprise a plurality of frequencies. This pulse impinges on beam splitter 19. The beam splitter splits the beam into a pump pulse 12 which is used to irradiate the sample and a probe pulse 14 which is used during detection.

The pump pulse 12 is directed into scanning delay line 16. This delay line is a rapid-scanning type and in its simplest form comprises two mirrors that serve to reflect the beam through a 180° angle. These mirrors are then quickly swept backwards and forwards in order to vary the path length of the pump pulse 12.

The output pump pulse from the scanning delay line 16 is then passed through AO modulator 17 to isolate reflected power from the laser and/or for modulation and directed by mirror 18 onto THz source 21. THz source 21 comprises a frequency conversion member and a bow-tie emitter. The frequency conversion member is configured to mix the incident radiation in order to output radiation derived from the differences of the input frequencies, so-called difference frequency generation. This technique is described in more detail in GB 2 347 835.

The emitter 21 abuts a hyper-hemispherical lens (not shown). The terahertz beam that is output from the emitter 21 is directed towards a first parabolic mirror 25. The beam is then reflected off the first parabolic mirror 25 and onto second parabolic mirror 26, which directs the radiation onto sample 30. The sample may be replaced with a reference sample in order to remove background features from the final results. The radiation which is reflected from sample 30 is then collected by third parabolic mirror 27 and directed onto a fourth parabolic mirror 28. Fourth parabolic mirror has a small aperture. The probe beam 14 is directed via mirror 41 through the aperture of fourth parabolic mirror 28 so that the probe beam can be combined with the radiation which has been reflected by the sample 30.

The combined THz radiation and probe beam then impinge on THz detector 29. In this particular embodiment, the THz detector is a photoconductive detector.

The components from the emitter 21, through the four parabolic mirrors and to the detector 29 form the imaging section 43.

The sample introduces a time delay in the path of the pump pulse. The delay is dependent on both the absorption coefficient and the refractive index of the sample. In order to obtain a detection signal, the frequency component of the probe beam must be in phase with a frequency component of the pump beam. Variation of the scanning delay line allows the phase of the probe beam and/or pump beam to be swept with respect to the pump beam and/or probe beam and thus allows for measurement of the delay time of each frequency component which passes through the sample.

This apparatus described can be utilised to obtain time domain data of a sample using broadband phase-sensitive Terahertz radiation. To generate an image, measurements of the THz signal can be obtained from a number of different parts of the sample. For example the area of the sample which is to be imaged is subdivided into a two dimensional array of pixels and the reflected radiation from each of the pixels is detected. This provides depth information for each pixel.

In the apparatus of FIG. 1, the imaging section 43 moves to scan the radiation across the sample. Alternatively, the sample may be moved relative to the beam of radiation.

Although a reflection system is described, it will be clear that the same principles may be applied to transmission systems where the detector (X) is provided on the opposite side of the sample (Y) to the emitter (Z). Either the emitter and detector may be scanned together with a transmission system or, more conveniently, the sample is scanned in a transmission system.

FIG. 2a shows a schematic of a liquid crystal display element 101. The liquid crystal element 101 comprises a first glass layer 103 onto which a thin film transistor (TFT) can be placed, and adjacent to the first glass layer, a first electrode layer 105. Adjacent the first electrode layer 105 there is a first polyamide layer 107. Adjacent the first polyamide layer is a liquid crystal layer 109. A liquid crystal layer 109 is sandwiched between first 107 and second 111 polyamide layers. Adjacent to the second polyamide layer 111 is a second electrode layer 113 together with adjacent second glass slide 115. A colour filter layer is frequently added to this layer.

It should be recognized that this is one structure. Passive and active LCDs from different manufacturers have different designs, and some of the layers above will or will not be included, dependent upon design. However, there should always be layers around the liquid crystal layer which give rise to a reflected THz pulse which can be used to isolate and identify the liquid crystal region.

FIG. 2b shows a plot of the amplitude of a terahertz waveform arising from a single pulse of radiation 117 which has been reflected from the LCD element 101. In this particular example, the incident pulse is first partially reflected off the entry surface into first glass slide layer 103. This partial reflection causes peak 121 in the plot of THz amplitude against time. As the pulse travels into further into element 101, it is next reflected from the liquid crystal region 109 between the polyamide layers and gives rise to second peak 123 in the terahertz time domain waveform. A weaker reflection is also seen from the final interface 115, the exit surface of the LCD element which gives rise to third peak 125 in the time domain waveform.

The first peak 121 does not contain any information concerning the liquid crystal layer 109 because the reflected radiation has not reached the liquid crystal region 109. The second peak 123 is reflected from the region of the liquid crystal 109 and will therefore carry information concerning this layer. Finally, the third peak will also contain information concerning the liquid crystal since it is generated by radiation which has passed through the element twice. This peak can also be used to monitor the presence of water and other contaminants in region around the liquid crystal, provided there are not other substantial changes in other parts of the structure at the same time.

One method of isolating information concerning the liquid crystal region is just to look at the second peak. Another method is to normalize the second peak with the first peak. This will allow better comparison of data measured in different regions of the sample.

FIG. 3 shows the distribution of the interface index across two samples. In the first sample, there is a liquid crystal layer in the second sample, there is not.

The interface index is:

$$\frac{\begin{matrix}Amplitude of the radiation reflected \\ from the liquid crystal region\end{matrix}}{Amplitude of the reflected radiation from the first interface} .$$

To obtain the data of FIG. 3, the interface index has been measured for a number of points on each sample. It can be seen that the sample with a liquid crystal layer, the mode of the interface index is approximately 55. However, in the structure without a liquid crystal layer, the mode of the interface index is approximately 60. This large variation in the interface index (11%) allows this technique to be used as a reliable technique for determining the presence of a liquid crystal layer within a liquid crystal structure.

The detection of the liquid crystal layer within an LCD relies upon changes in the terahertz refractive index and absorption properties when going from the glass slide into the region with the crystal. In turn, the presence of impurities such as water in this layer will also cause changes in the measured refractive and hence interface indices. Comparing liquid water with liquid crystals, in the terahertz region, there is ˜35% difference in refractive indices and ˜×10 difference in absorption between water and liquid crystals. Therefore, it is possible use terahertz to determine the presence of water within an LCD structure.

Water has been placed within the structure in region 153 of FIG. 4a. This water is not visible using optical radiation. However, it is indicated on the figure to aid understanding.

FIG. 4b shows a terahertz image generated by plotting the interface index for different parts of the LCD, where the interface index is plotted as part of a greyscale image; different shades of grey correspond to different intensities. The interface index corresponds to pulse 123 in FIG. 2b from the region around the liquid crystal. In the section where there is large water content 115 it can be seen that there is a large difference in the interface index in section 157 where there is no water. Actually, there is 20% difference in the interface index as water yields a 20% lower interface index than liquid crystal alone. Thus, water contamination can easily be detected. The exact magnitude and sign of the change corresponding to regions with water contamination will depend upon the layer structure used in the LCD.

FIG. 5a shows a 3D schematic of a structure similar to an LCD. The structure comprises first 201 and second 203 glass slides separated by a polytetrafluoroethylene (PTFE), spacer 207. The PTFE space 207 has a water channel 209 and leakage from that water channel 211 is shown. A transparent electrode and polyamide layer 205 is present between the PTFE spacer 207 and the second glass slide.

FIG. 5b is a plot of the interface index calculated using terahertz radiation by analysing the pulse passing through the liquid crystal and reflected from back of the LCD (pulse 125 in FIG. 2b). The water channel 209 and water leakage 211 can be easily seen in the terahertz image constructed from the interface index.

FIG. 6 also uses the structure shown in FIG. 5a. FIG. 6a is a visible image showing the structure when it can be seen that there is no variation in the visible image. FIG. 6c shows a terahertz time domain trace of two points indicated on FIG. 6b. The first point 251 is in a region where there is water and corresponds to the trace 251 and the second trace 253 corresponds to a region without water. It can be seen that the amplitude of the reflected terahertz waveform is larger in the region without water. It should be noted that this is not the interface index reflection measurement. In a reflection measurement, the x-axis of the time delay can be converted into the penetration depth of the radiation.

FIG. 7 shows the plot of FIG. 6c which has been converted into the frequency domain via a Fourier transform. The upper trace 261 shows the terahertz waveform in the region where there is no water, the lower trace 263 shows the terahertz waveform in the region where there is water.

The dotted lines show the theoretical spectra of liquid water in the terahertz regime 265 and the theoretical spectra acetone which is marked as 267. Thus, it is also possible to determine the type of contamination present by looking at the spectra obtained.

FIG. 8a shows a magnified visible photograph of an LCD structure. The position of defects are marked. However, it is clear from the photograph that they cannot be seen in the visible spectrum.

FIGS. 8b shows exactly the same sample but this time with the image taken in the terahertz regime where defects can be easily noted as indicated by the rings;

Although the description has primarily described reflection measurements, it is also possible to use transmission measurements to analyse an LCD. FIG. 9 is a further schematic of the LCD element originally shown in FIG. 2a. To avoid unnecessary repetition like reference numerals will be used to denote like features.

There are two broad approaches to obtaining data from transmission measurements. First, the pulse which passes through the structure cleanly (i.e. without any internal reflections) can be studied. This is easy to identify as it is will be the largest pulse signal measured which has been transmitted through the structure. It is possible to monitor the height of the peak at different times in the time domain profile. The height of the peak will be affected considerably by water absorption if water is present and this provides another technique for determining water contamination or looking for the presence of other defects or contamination. The data obtained may be compared with that of a known sample or an image of the sample under test may be constructed to show irregularities in the sample.

As for reflection measurements, it is also possible to convert time domain data into frequency domain data in order to perform spectral analysis.

Another method is to use pulses which are transmitted through the structure, but which have undergone secondary reflections such as the path shown as 303. These pulses may be analysed in the same way as the pulses which are reflected from the sample

For analysing multiple LCD elements, a robot arm of the type shown in FIG. 10 may be employed. An LCD element may be picked up by the arm, moved into a position for THz investigation, replaced after measurements have been made and the next LCD element may then be tested.

1. A method configured to investigate an LCD structure, the method comprising:
irradiating an LCD structure with pulsed radiation having at least one frequency in the range from 40 GHz to 100 THz;
detecting radiation which has been transmitted through or reflected by the structure;
determining information about the structure by measuring a quantity at least related to the amplitude of the detected radiation.

2. A method according to claim 1, configured to investigate a layer or plurality of layers located inside said structure, further comprising identifying at least one pulse from the detected radiation which has been influenced by said layer or layers.

3. A method according to claim 2, wherein said layer or plurality of layers have a thickness of at most 50 μm.

4. A method according to claim 2, wherein said layer or plurality of layers are located between two interfaces which are opaque to visible light.

5. A method according to claim 2, configured to investigate the liquid crystaTlayer of an LCD structure, wherein said pulse is identified from the region of the liquid crystal layer.

6. A method according to claim 5, wherein the presence or absence of a liquid crystal layer is determined.

7. A method according to claim 5, configured to determine contamination within a liquid crystal layer.

8. A method according to claim 7, wherein the contaminant is water.

9. A method according to claim 7, comprising determining spectral information from the region where a liquid crystal layer should be located to identify contaminants.

10. A method according to claim 6, wherein the detected radiation is compared with a reference.

11. A method according to claim 1, wherein radiation reflected from the structure is detected.

12. A method according claim 11 configured to investigate a layer or plurality of layers located inside said structure, further comprising identifying at least one pulse from the detected radiation which has been influenced by said layer or layers, wherein the pulse is identified by locating the peaks arising from reflections at the interfaces of the layer or layers.

13. A method according to claim 12, wherein the amplitude of the radiation which has passed through a layer or layers of interest is divided by the amplitude of detected radiation which has not passed through this layer or layers.

14. A method according to claim 1, wherein radiation which is transmitted through the structure is detected.

15. A method according to claim 1, wherein the detected radiation is analysed in the time domain.

16. A method according to claim 1, wherein the detected radiation is analysed in the frequency domain.

17. A method according to claim 1, wherein a plurality of measurements are performed at different points across the structure.

18. A method according to claim 17, further comprising forming an image of the sample using the plurality of measurements.

19. A method according to claim 18, wherein the image is constructed from pulses of detected radiation from a layer or layers located within the LCD.

20. An apparatus for investigating an LCD structure, comprising:
a mount configured to hold an LCD for investigation;
a source of THz radiation configured to irradiating an LCD located in said mount with pulsed radiation having at least one frequency in the range from 40 GHz to 100 THz;
a detector for detecting radiation which has been transmitted through or reflected by the LCD; and
a computer for determining information about the LCD by measuring a quantity at least related to the amplitude of the detected radiation.

21. An apparatus according to claim 20, wherein the mount is moveable to allow the LCD to be imaged.

22. An apparatus according to claim 20, wherein the source and detector are moveable to allow the LCD to be imaged.

23. An apparatus according to claim 20, wherein the mount is provided on a robot arm.
